(19) United States
(12) Patent Application Publication
(10) Pub. No.: US 2024/0290524 A1
(43) Pub. Date: Aug. 29, 2024

(54) ELECTROMAGNETIC ABSORBER AND METHOD FOR MANUFACTURING SAME

(71) Applicant: TOHOKU UNIVERSITY, Sendai-shi, Miyagi (JP)

(72) Inventor: Satoshi SUGIMOTO, Sendai-shi (JP)

(21) Appl. No.: 18/567,945

(22) PCT Filed: Jun. 16, 2022
(86) PCT No.: PCT/JP2022/024143

§ 371 Date: Dec. 7, 2023

(30) Foreign Application Priority Data
Jun. 17, 2021 (WO) PCT/JP2021/023045

(51) Int. Cl. H01F 1/20; B22F 1/068; B22F 1/10; B22F 1/142; C08J 3/20; C08K 3/08; C22C 38/30; H05K 9/00

(52) U.S. Cl. CPC H01F 1/20; B22F 1/068; B22F 1/10; B22F 1/142; C08J 3/203; C08K 3/08; C22C 38/30; H05K 9/0081; B22F 2301/35; B22F 2999/00; C08K 2003/0856; C08K 2201/01; C08K 2201/016

(57) ABSTRACT

An electromagnetic absorber includes a base material formed of a polymer, and a powder dispersed in the base material. The powder is formed of an Fe—Cr—Co-based alloy having a two-phase separation structure including a first phase and a second phase. An Fe content and a Co content of the first phase are more than those of the second phase, and a Cr content of the second phase is more than that of the first phase. The two-phase separation structure is a modulated structure. Preferably, the first phase is elongated or flattened.

The present application claims priority based on PCT/JP2021/023045 filed to World Intellectual Property Organization on Jun. 17, 2021, and contents thereof are incorporated herein by reference.

### TECHNICAL FIELD

The present invention relates to an electromagnetic absorber and a method for manufacturing the same.

### BACKGROUND ART

In recent years, due to development of Internet of Things (IoT) devices, electromagnetic interference in electronic devices has been regarded as a problem. As a countermeasure against electromagnetic interference, an electromagnetic absorber formed of magnetic powder and a resin has attracted attention. The electromagnetic absorber has a function of absorbing unnecessary electromagnetic waves and converting them into heat.

However, an electromagnetic wave absorption capability of the electromagnetic absorber depends on a frequency of electromagnetic waves. In recent years, due to an increase in speed of wireless communication, this frequency dependence becomes a problem. In order to increase the speed of wireless communication, a situation in which a high-frequency electromagnetic wave is used is increasing. In the related art, an electromagnetic absorber can absorb a relatively low-frequency electromagnetic wave, but cannot exhibit a sufficient electromagnetic wave absorption capability for the high-frequency electromagnetic wave.

Further, the electromagnetic wave absorption capability of the electromagnetic absorber also depends on a thickness thereof. As the thickness increases, the electromagnetic wave absorption capability increases. However, in recent years, electronic devices have been increasingly reduced in size. Therefore, an electromagnetic absorber that is thin and has a high electromagnetic wave absorption capability is required.

Examples of electromagnetic absorbers known in the related art are as follows.

PTL 1 discloses a polymer composition for a magnetic member, including a base polymer and a powder dispersed in the base polymer, the powder being composed of a large number of flaky particles, the flaky particles being composed of an Fe-based alloy including: 6.5% by mass or more and 32.0% by mass or less of Ni; 6.0% by mass or more and 14.0% by mass or less of Al; 0% by mass or more and 17.0% by mass or less of Co; and 0% by mass or more and 7.0% by mass or less of Cu, the balance being unavoidable impurities.

PTL 2 discloses a soft magnetic or semi-hard magnetic material, the magnetic material including: a first phase having crystals with a bcc or fcc structure containing Fe and Co; and a second phase containing Co, in which a Co content contained in the second phase when a total of Fe and Co is 100 atom % is more than a Co content contained in the first phase when a total of Fe and Co is 100 atom %.

However, even with this technique, it is not easy to provide an electromagnetic absorber having a high electromagnetic wave absorption capability for high-frequency electromagnetic wave.

### CITATION LIST

### Patent Literature

PTL 1: JP2020-152979A
PTL 2: WO2019/059256

### SUMMARY OF INVENTION

### Technical Problem

An object of the invention is to provide an electromagnetic absorber having a high electromagnetic wave absorption characteristic in a high-frequency band, and a method for manufacturing the same.

### Solution to Problem

A gist of the invention is as follows.

(1) An electromagnetic absorber according to an aspect of the invention includes: a base material formed of a polymer; and a powder dispersed in the base material, the powder is formed of an Fe—Cr—Co-based alloy having a two-phase separation structure including a first phase and a second phase, an Fe content and a Co content of the first phase are more than those of the second phase, a Cr content of the second phase is more than that of the first phase, and the two-phase separation structure is a modulated structure.

(2) In the electromagnetic absorber according to the above (1), preferably, the first phase is elongated or flattened.

(3) In the electromagnetic absorber according to the above (1) or (2), preferably, the first phase has an elliptical plate shape or a circular plate shape elongated in one direction.

(4) In the electromagnetic absorber according to any one of the above (1) to (3), preferably, an average aspect ratio of the powder is within a range of 3 to 50, and the first phase is flattened accordingly.

(5) In the electromagnetic absorber according to any one of the above (1) to (4), preferably, components of the powder contain Cr: 10 to 50 mass %, Co: 0 to 30 mass %, and one or more selected from the group consisting of Ti, Zr, Hf, Al, V, Nb, and Si: 0 to 5 mass % in total, with the balance being Fe and impurities.

(6) A method for manufacturing an electromagnetic absorber according to another aspect of the invention includes: a step of forming a two-phase separation structure including a first phase and a second phase by causing spinodal decomposition in a metal structure of a powder formed of an Fe—Cr—Co-based alloy, in which an Fe content and a Co content of the first phase are more than those of the second phase, and a Cr content of the second phase is more than that of the first phase; and a step of obtaining an electromagnetic absorber by kneading and shaping the powder with a base material formed of a polymer.

(7) The method for manufacturing an electromagnetic absorber according to the above (6) preferably further includes a step of elongating or flattening the first phase.

(8) In the method for manufacturing an electromagnetic absorber according to the above (7), preferably, the step of elongating or flattening the first phase is a step of elongating and/or flattening the powder having the two-phase separation structure between the step of forming the two-phase separation structure and the step of obtaining the electromagnetic absorber, so that the powder has an average aspect ratio within a range of 3 to 50.

(9) In the method for manufacturing an electromagnetic absorber according to any one of the above (6) to (8), preferably, the spinodal decomposition is caused by holding the powder at a temperature equal to or lower than that of a two-phase separation surface.

(10) In the method for manufacturing an electromagnetic absorber according to any one of the above (6) to (9), preferably, components of the powder contain Cr: 10 to 50 mass %, Co: 0 to 30 mass %, and one or more selected from the group consisting of Ti, Zr, Hf, Al, V, Nb, and Si: 0 to 5 mass % in total, with the balance being Fe and impurities.

### Advantageous Effects of Invention

According to the invention, it is possible to provide an electromagnetic absorber having a high electromagnetic wave absorption characteristic in a high-frequency band, and a method for manufacturing the same.

### BRIEF DESCRIPTION OF DRAWINGS

FIG. 1 is a schematic cross-sectional view of an electromagnetic absorber according to an embodiment of the invention.

FIG. 2 is a photograph of a structure of an example of an Fe—Cr—Co-based alloy before spinodal decomposition.

FIG. 3A is a photograph of a structure of an example of an Fe—Cr—Co-based alloy after spinodal decomposition.

FIG. 3B is an element mapping image of an example of the Fe—Cr—Co-based alloy after spinodal decomposition.

FIG. 4 shows an example of a heat treatment condition for causing spinodal decomposition.

FIG. 5 is a photograph of an example of a powder after flattening treatment.

FIG. 6 is a graph showing a relation between heat treatment time and saturation magnetization σₛ and coercive force H_{c}.

FIG. 7 is a graph showing a relation between the heat treatment time and a resonance frequency fᵣ and complex relative permeability μᵣ.

FIG. 8 is a graph showing a relation between the heat treatment time and reflection loss R.L.

FIG. 9 is a graph that evaluates a high-frequency magnetic characteristic of a powder after flattening.

FIG. 10 is a graph that evaluates an electromagnetic wave absorption characteristic of the powder after flattening.

FIG. 11 is a graph showing a relation between a flattening condition and an aspect ratio of a powder.

FIG. 12 is a graph showing a relation between the flattening condition and a magnetic characteristic of a powder.

FIG. 13 is an element mapping image of an example of an Fe—Cr—Co-based alloy after spinodal decomposition and ball milling treatment.

FIG. 14A shows an example of a manufacturing method to which an elongating method and a flattening method are not applied.

FIG. 14B shows an example of a manufacturing method to which flattening of a powder is applied.

FIG. 14C shows an example of a manufacturing method to which an elongating method for causing spinodal transformation while applying a magnetic field is applied.

FIG. 14D shows an example of a manufacturing method to which a combination of the elongating method for causing spinodal transformation while applying a magnetic field and flattening of a powder is applied.

FIG. 14E shows an example of a manufacturing method to which a combination of elongation of a powder and flattening of a powder is applied.

FIG. 15 shows an observation result of a flattened first phase.

FIG. 16 is a graph showing an evaluation result of a complex relative permeability characteristic of a powder after flattening.

FIG. 17 is a graph showing an effect of flattening treatment on fₘ×dₘ in the reflection loss R.L.

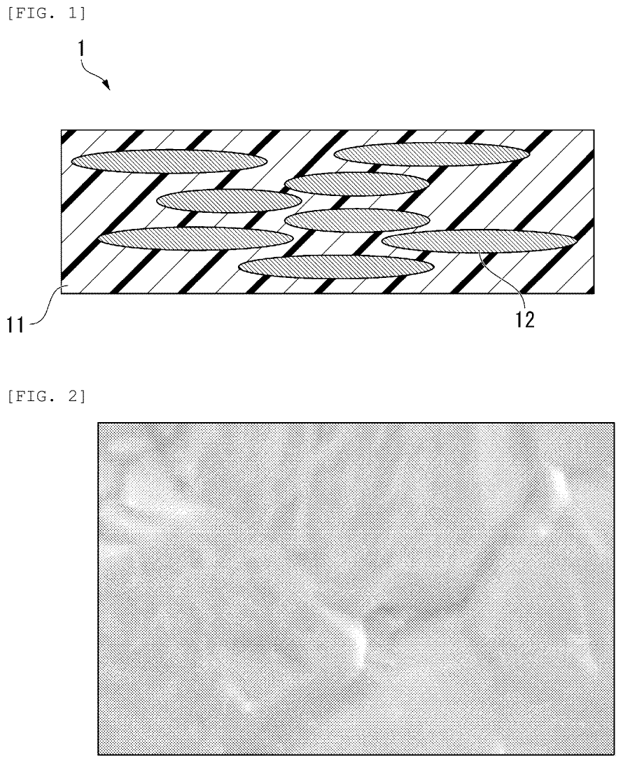

### DESCRIPTION OF EMBODIMENTS

An electromagnetic absorber 1 according to an aspect of the invention includes a base material 11 formed of a polymer and a powder 12 dispersed in the base material 11. The powder 12 is formed of an Fe—Cr—Co-based alloy separated into two phases, an Fe content and a Co content of a first phase are more than those of a second phase, and a Cr content of the second phase is more than that of the first phase. In addition, the two-phase separation structure is a modulated structure. Hereinafter, a preferred embodiment of the invention will be described in detail.

### (1. With Respect to Base Material 11)

The base material 11 is formed of, for example, a polymer such as a resin and rubber. By kneading and shaping the powder 12 having a predetermined configuration to be described later into the base material 11, the electromagnetic absorber 1 in which the powder 12 is dispersed in the base material 11 can be obtained.

A type of the polymer forming the base material 11 is not particularly limited. This is because the electromagnetic absorber 1 exhibits an electromagnetic wave absorption capability using the powder 12, not using the base material 11. Therefore, an appropriate material according to an application of the electromagnetic absorber 1 can be appropriately selected as the base material 11. A shape of the base material 11 is not particularly limited, and can be appropriately selected according to the application of the electromagnetic absorber 1. For example, the electromagnetic absorber 1 can be easily disposed inside an electronic device by molding the base material 11 into a thin sheet shape using a polymer having flexibility. A substance other than the powder 12 may be kneaded with the base material 11. For example, the base material 11 may contain a processing aid such as a lubricant and a binder, a flame retardant, and the like.

### (2. With Respect to Powder 12)

The powder 12 is an Fe—Cr—Co-based alloy having a two-phase separation structure generated by spinodal decomposition. In general, the spinodal decomposition refers to phase separation corresponding to a state change from an unstable state to an equilibrium state, and the phase separation proceeds due to growth of concentration fluctuation without requiring nucleation. In the powder 12 of the electromagnetic absorber 1 according to the present embodiment, two-phase separated transformation occurring in a transition from a state in which a metal structure thereof is heated to a temperature range where the metal structure is substantially an a-phase single phase to a state in which the temperature is lowered to a two-phase temperature range is referred to as spinodal decomposition. In general, a spinodally decomposed structure shows a modulated structure. The modulated structure refers to a structure including regular fine concentration fluctuation. For example, page 149 of “Metallography” by Hajime Sudo, Imao Tamura, and Taiji Nishizawa, published by Maruzen Co., Ltd., Japan, published on Aug. 31, 1972, explained the modulated structure, and a Cu—Ni—Fe-based alloy is exemplified as an example of an alloy having the modulated structure.

By the spinodal decomposition, the powder 12 includes a first phase rich with Fe and Co and a second phase rich with Cr. Specifically, in the two-phase separation structure, an Fe content and a Co content of the first phase are more than those of the second phase, and a Cr content of the second phase is more than that of the first phase. In an Fe-based alloy, a peak of an electromagnetic wave absorption characteristic can be shifted to a high-frequency side by causing two-phase separation.

Further, in the powder 12 of the electromagnetic absorber 1 according to the present embodiment, it is preferable that the first phase rich with Fe and Co is elongated or flattened. Accordingly, the electromagnetic wave absorption capability of the electromagnetic absorber 1 on the high-frequency side can be further enhanced. By enhancing the electromagnetic wave absorption capability of the electromagnetic absorber 1, a thickness of the electromagnetic absorber 1 can be reduced. “Elongation of the first phase” means that the first phase is extended along one direction, and “flattening of the first phase” means that the first phase is extended radially along a plane.

An example of a method for flattening the first phase contained in the powder 12 is flattening of the powder 12. For example, the flattening is performed after the powder 12 is subjected to the spinodal decomposition, and an average aspect ratio of the powder 12 is in a range of 3 to 50, so that the first phase can be suitably flattened, and the electromagnetic wave absorption capability on the high-frequency side can be dramatically enhanced.

However, it should be noted that when the spinodal decomposition is caused after the flattening, the flattening of the powder 12 is achieved but the flattening of the first phase is not achieved. In this case, a granular first phase is formed inside the flattened powder 12.

When heat treatment for causing the spinodal decomposition is performed at a temperature equal to or lower than that of a two-phase separation surface, workability of the powder 12 is slightly reduced, and the flattening becomes difficult to perform. Therefore, if the powder 12 is flattened as a purpose of processing, the flattening should be performed before the spinodal decomposition occurs. Even if the flattening of the first phase is not achieved, a slight improvement in characteristics can be expected as long as the flattening of the powder 12 is achieved. However, according to findings of the present inventors, an element that decisively influences an improvement effect of an electromagnetic characteristic by the flattening is not a shape of the powder 12 but a shape of the first phase contained in the powder 12. In order to dramatically enhance the electromagnetic wave absorption capability of the electromagnetic absorber 1, it is preferable to flatten the first phase.

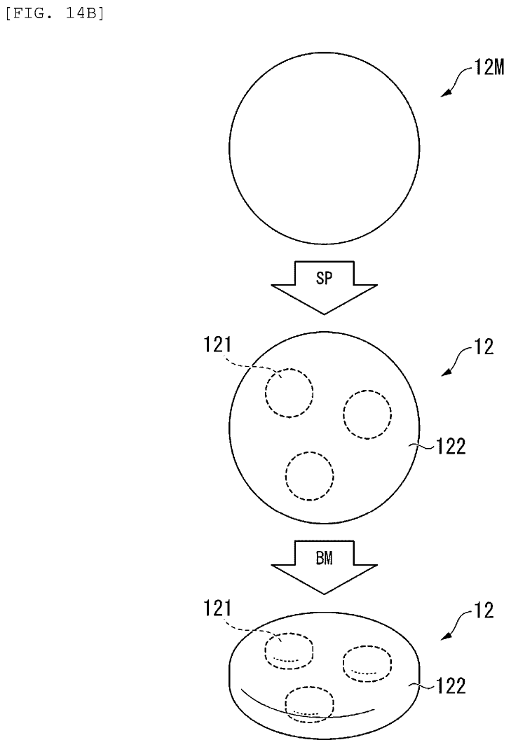

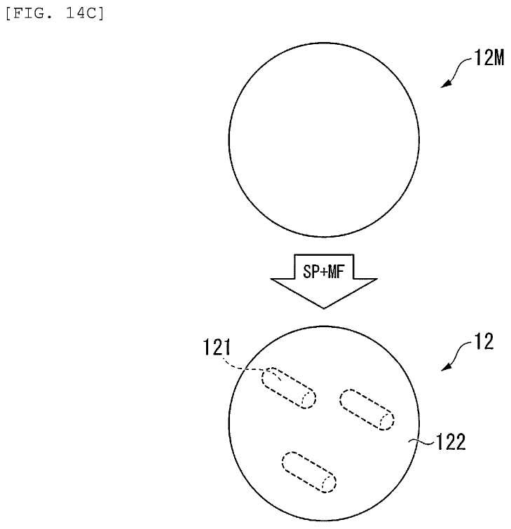

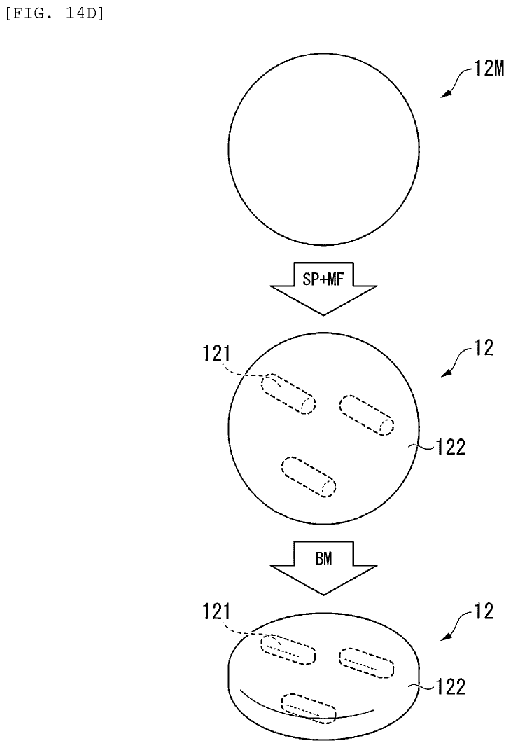

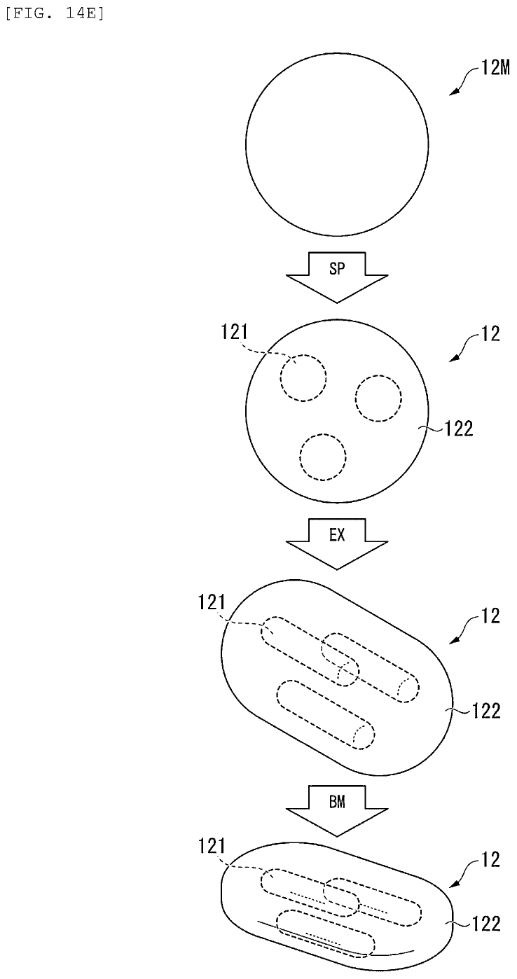

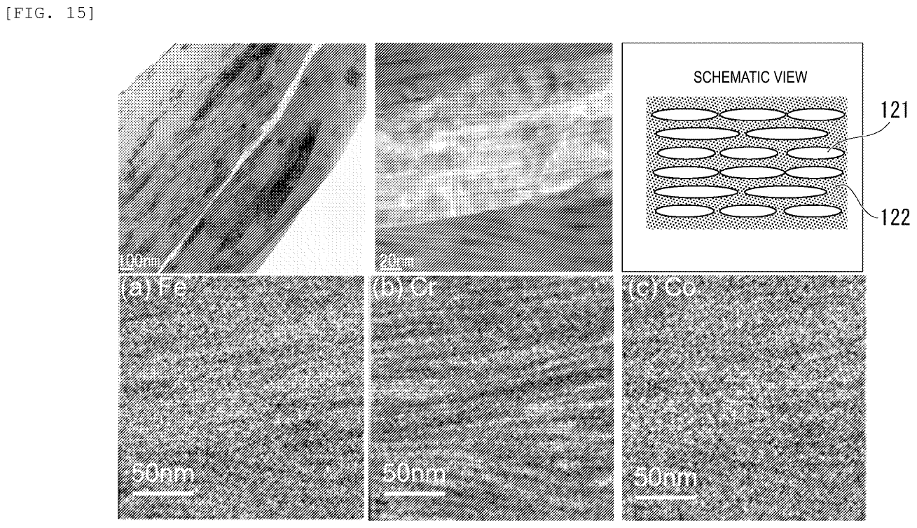

One example of a method for elongating the first phase contained in the powder 12 is to cause the spinodal decomposition while applying a magnetic field to the powder 12. In general, after the spinodal decomposition, as schematically shown in FIG. 14A, the first phase is formed in a granular shape. The average aspect ratio is a value close to 1. On the other hand, when the spinodal decomposition is caused while applying the magnetic field to the powder 12, the first phase formed in the powder 12 has a shape in which grains are extended along one direction. Accordingly, the first phase can be elongated without flattening the powder 12.

Another example of a method for elongating the first phase contained in the powder 12 is elongation of a powder after the spinodal decomposition. For example, the first phase can be elongated in the same direction as a processing direction of the powder 12 by filling the powder 12 into a pipe-shaped container after the spinodal decomposition and processing the powder 12 along one direction with respect to the container.

The above-described methods may be appropriately combined. An example of a specific manufacturing method that obtains the powder 12 having the first phase will be described below with reference to the drawings.

FIG. 14A shows an example in which the above-described elongating method and the flattening method are not applied. In the manufacturing method shown in FIG. 14A, the powder 12 having a two-phase separation structure formed of a first phase 121 and a second phase 122 is obtained by performing only the heat treatment for causing the spinodal decomposition on a powder before the heat treatment. (hereinafter referred to as a “material powder 12M”). In this case, the powder 12 and the first phase 121 are neither elongated nor flattened.

FIG. 14B shows an example in which the flattening of the powder 12 is applied. In a manufacturing method shown in FIG. 14B, first, a material powder 12M is subjected to the heat treatment to obtain the powder 12 having the two-phase separated structure formed of the first phase 121 and the second phase 122. Next, the powder 12 is flattened. Accordingly, the powder 12 can be flattened, and the first phase 121 contained in the powder 12 can also be flattened.

FIG. 14C shows an example in which an elongating method for causing spinodal transformation while applying a magnetic field is applied. In a manufacturing method shown in FIG. 14C, the material powder 12M is subjected to the heat treatment for causing the spinodal decomposition while applying a magnetic field in one direction. Accordingly, the powder 12 having a two-phase separation structure formed of the first phase 121 and the second phase 122 elongated along the magnetic field is obtained. The first phase 121 elongated along the magnetic field is also referred to as a needle-shaped structure. On the other hand, according to the manufacturing method in FIG. 14C, the powder 12 is neither elongated nor flattened.

FIG. 14D shows an example in which a combination of the elongating method for causing spinodal transformation while applying a magnetic field and flattening of a powder is applied. In a manufacturing method shown in FIG. 14D, first, the material powder 12M is subjected to the heat treatment for causing the spinodal transformation while applying the magnetic field to obtain the powder 12 in which the first phase 121 is elongated. Next, the powder 12 is flattened. According to the manufacturing method in FIG. 14D, the powder 12 is flattened. According to the manufacturing method in FIG. 14D, the first phase 121 has an elliptical plate shape or a circular plate shape elongated in one direction. A shape of the first phase 121 obtained by the manufacturing method in FIG. 14D may also be referred to as a koban shape (that is, an elliptical Japanese gold coin in the Edo Period).

FIG. 14E shows an example in which a combination of elongation of a powder and flattening of a powder is applied. In a manufacturing method shown in FIG. 14E, first, the material powder 12M is subjected to heat treatment for causing spinodal decomposition to obtain the powder 12 having the two-phase separation structure formed of the first phase 121 and the second phase 122. Next, the powder 12 is elongated to obtain the powder 12 elongated in one direction. The elongated powder 12 contains the first phase 121 elongated in one direction. Further, the powder 12 is flattened. Accordingly, the powder 12 having the elliptical plate shape or the circular plate shape elongated in one direction is obtained. The first phase 121 contained in the powder 12 also has the elliptical plate shape or the circular plate shape elongated in one direction.

In any of the manufacturing methods, the flattening or elongating needs to be performed on the powder 12 after the spinodal transformation. When the material powder 12M is flattened or elongated and then subjected to the heat treatment, the flattened or elongated powder 12 is obtained, and the first phase 121 contained in the powder 12 has a spherical shape.

Specific components of the Fe—Cr—Co-based alloy may be those capable of forming the two-phase separation structure formed of the first phase rich with Fe and Co and the second phase rich with Cr. Including elements other than Fe, Cr, and Co is allowed. For example, components of the Fe—Cr—Co-based alloy may contain Cr: 10 to 50 mass %, Co: 0 to 30 mass %, and one or more selected from the group consisting of Ti, Zr, Hf, Al, V, Nb, and Si: 0 to 5 mass % in total, with the balance being Fe and impurities. By setting contents of Cr and Co within the above-described ranges, a preferable two-phase separation structure can be formed.

Ti is not an essential component in the powder 12 of the electromagnetic absorber 1 according to the present embodiment. Therefore, a lower limit of a Ti content is 0%. However, by containing an appropriate amount of Ti in the powder 12, the powder 12 before the spinodal decomposition can be made into an α single phase, and a uniform two-phase separation structure can be formed. Further, Ti also has a function of preventing a decrease in an amount of Cr due to oxidation. Therefore, 0.5% or more of Ti may be contained in the powder 12. In addition to Ti, V, Nb, Zr, Al, Hf, and Si also have the same function, and thus may be contained in the powder 12 similarly to Ti. In this case, the above-described Ti content may be applied to a total content of these elements. That is, one or more elements selected from the group consisting of Ti, Zr, Hf, Al, V, and Nb may be contained in the powder 12, and a total content of these elements may be 0 to 5%. Preferably, the total content of one or more selected from the group consisting of Ti, Zr, Hf, Al, V, and Nb is 0.5% or more.

An element other than Fe, Cr, Co, Ti, V, Nb, Zr, Al, Hf, and Si may also be contained in the powder 12 as an impurity or as a component to be intentionally added within a range that does not interfere with a magnetic characteristic and workability of the powder 12. For example, Mo is an element that increases coercive force and may be contained in the powder 12.

On the other hand, it is preferable to remove an element impairing these characteristics from the powder 12. The powder 12 of the electromagnetic absorber 1 according to the present embodiment does not contain Ni as an essential component.

As described above, the average aspect ratio of the powder 12 is preferably in a range of 3 to 50. By kneading and shaping the powder 12 having an average aspect ratio of 3 or more into the base material 11, the first phase rich with Fe and Co can be flattened, a magnetic path can be formed inside the electromagnetic absorber 1, and an actual part transmittance μ′ of the electromagnetic absorber 1 can be increased. A lower limit of the average aspect ratio is preferably 5, 8, 10, 15, 18, or 30. From a viewpoint of preventing pulverization of the powder 12, an upper limit of the average aspect ratio of the powder 12 is preferably 50, 40, 30, or 20.

A size of the powder 12 is not particularly limited, and for example, an average equivalent circular diameter thereof is preferably 50 μm to 300 μm. The equivalent circular diameter of the powder 12 may be 100 μm or less. On the other hand, when an average thickness of the powder 12 is 10 μm or less, further improvement of the magnetic characteristic can be expected.

A method for evaluating various characteristics of the powder 12 of the electromagnetic absorber 1 are as follows.

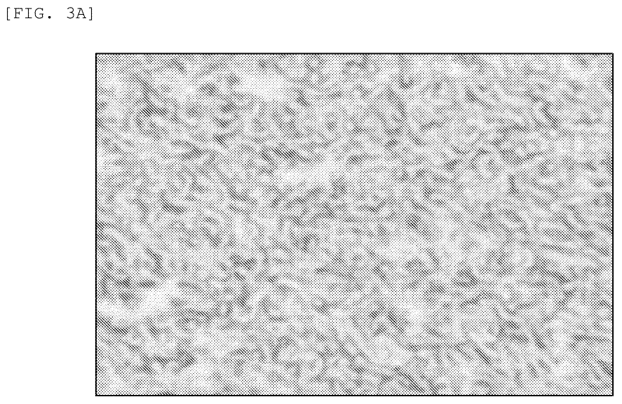

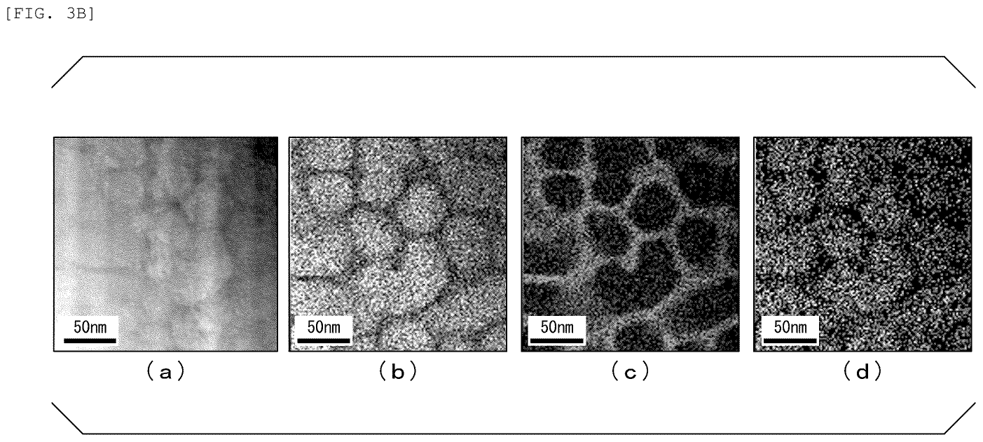

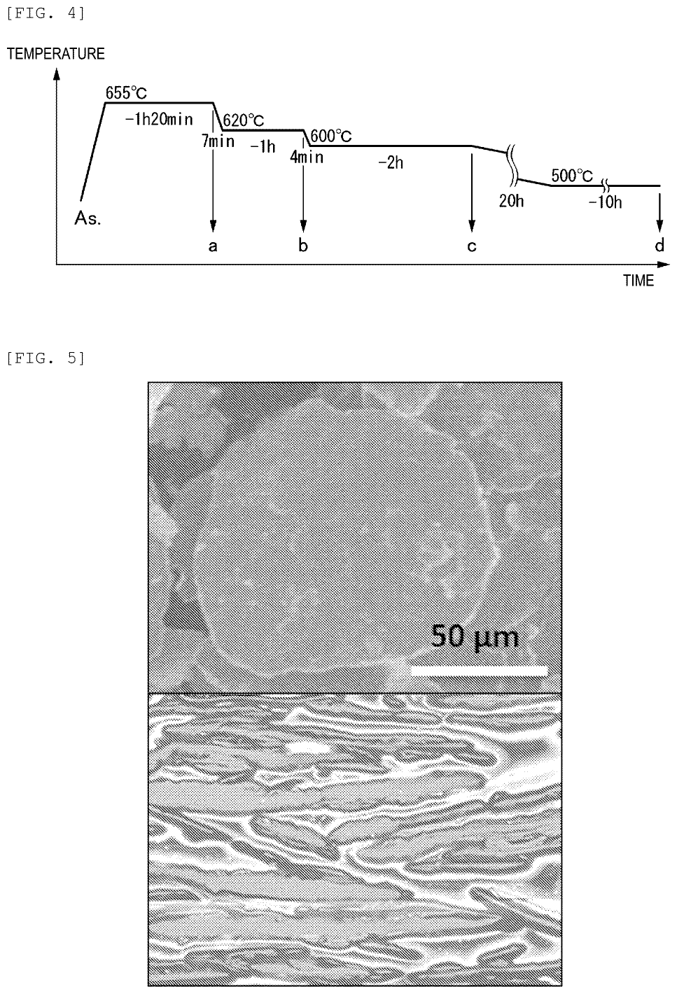

A structure of the powder 12 can be evaluated by cutting the electromagnetic absorber 1, appropriately adjusting a cut surface, and capturing a reflected electron image by an SEM or a TEM. The first phase and the second phase can be clearly confirmed in the reflected electron image due to a difference in density. FIG. 2 shows a reflected electron image of an ordinary Fe—Cr—Co-based alloy powder in which the spinodal decomposition does not occur, and FIG. 3 shows a reflected electron image of an Fe—Cr—Co-based alloy powder having the two-phase separation structure formed of the first phase rich with Fe and Co and the second phase rich with Cr. The ordinary Fe—Cr—Co-based alloy powder shows a flat property in the reflected electron image. On the other hand, the Fe—Cr—Co-based alloy powder having the two-phase separation structure exhibits a complicated shading pattern in the reflected electron image. Therefore, presence or absence of the two-phase separation structure can be easily confirmed by observation by the SEM or the TEM. Further, by measuring element concentration distribution during observation by TEM, the first phase rich with Fe and Co and the second phase rich with Cr can be distinguished.

An aspect ratio of the powder 12 can also be evaluated by cutting the electromagnetic absorber 1, appropriately adjusting the cut surface, and capturing an enlarged image by an optical microscope, a laser microscope, the SEM, or the TEM. In the enlarged image of the cut surface, the base material 11 and the powder 12 can be easily distinguished. A major axis of the powder 12 and a minor axis of the powder 12 measured in a direction perpendicular to the major axis are obtained, and ratios thereof are calculated to obtain aspect ratios of the powder 12. The average aspect ratio of the powder 12 of the electromagnetic absorber 1 can be obtained by repeatedly performing this procedure on a large amount of the powder 12 and calculating an average value of the obtained aspect ratios.

When the shape of the powder 12 is a flat shape, an aspect ratio of the powder is a ratio between a diameter (a) and a thickness (c) of the powder, that is, a/c. On the other hand, when the shape of the powder 12 is an elongated shape, the aspect ratio of the powder is a ratio of an average value ((a+b)/2) of a diameter (a) in a longitudinal direction and a diameter (b) in a short direction of the powder to the thickness (c), that is, ((a+b)/2)/c.

Components of the powder 12 can be evaluated by measuring an average composition by an SEM attached to an energy dispersive X-ray spectrometer (EDX) and then measuring compositions of the first phase and the second phase after two-phase separation using the TEM.

The equivalent circular diameter of the powder 12 can be also evaluated by cutting the electromagnetic absorber 1, appropriately adjusting the cut surface, and capturing the enlarged image by the SEM or the TEM. An area of the powder 12 included in the enlarged image is obtained, and then a diameter of a circle thereof is calculated assuming that a cross section of the powder 12 is the circle. The average equivalent circular diameter of the powder 12 of the electromagnetic absorber 1 can be obtained by repeatedly performing this procedure on a large amount of the powder 12 and calculating an average value of obtained equivalent circular diameters.

Next, an example of a preferable method for manufacturing the electromagnetic absorber 1 according to the present embodiment will be described. The method for manufacturing the electromagnetic absorber 1 is not particularly limited, and all the electromagnetic absorbers having the above-described configuration are regarded as the electromagnetic absorber 1 according to the present embodiment, and according to a manufacturing method to be described later, the electromagnetic absorber 1 according to the present embodiment can be suitably manufactured.

First, spinodal decomposition is caused in a metal structure of the powder 12 formed of the Fe—Cr—Co-based alloy to form a two-phase separation structure. As described above, the two-phase separation structure includes the first phase and the second phase, and is a structure in which an Fe content and a Co content of the first phase are more than those of the second phase, and a Cr content of the second phase is more than that of the first phase. Next, the powder is kneaded and shaped with a base material formed of a polymer to obtain an electromagnetic absorber. A specific method for causing the spinodal decomposition in the powder is not particularly limited, and examples thereof include the following.

The spinodal decomposition can be caused by heat treatment in which the powder 12 is first subjected to solution treatment to form the metal structure thereof into an α single phase, and then the powder 12 is slowly cooled. The α single phase may be prepared by preparing a powder by atomization instead of the solution treatment. Thereafter, by holding the powder at a temperature equal to or lower than that of a two-phase separation surface, the spinodal decomposition can be caused in the powder. For example, isothermal aging treatment, multistage aging treatment, or continuous cooling treatment may be performed once at a temperature equal to or lower than that of the two-phase separation surface. The temperature of the two-phase separation surface varies depending on components of the powder, and can be obtained based on a known Fe—Cr—Co ternary phase diagram.

FIG. 4 shows a more specific example of a heat treatment condition. As shown in FIG. 4 is a state after the solution treatment, and heat treatment corresponding to a, b, c, and d is performed by
(A) holding a temperature of the powder 12 in a first temperature range of 655° C.±10° C., which is equal to or lower than a temperature of the two-phase separation surface, for 80 minutes,
(B) lowering the temperature of the powder 12 held in the first temperature range to a second temperature range of 620° C.±10° C. and holding the temperature for 60 minutes or more,
(C) lowering the temperature of the powder 12 held in the second temperature range to a third temperature range of 600° C.±10° C. and holding the temperature for 120 minutes or more, and
(D) lowering the temperature of the powder 12 held in the third temperature range to a fourth temperature range of 500° C.±10° C. and holding the temperature for 600 minutes or more.

The solution treatment is a stage prior to the spinodal decomposition. When the solution treatment is completed, it is estimated that the metal structure of the powder 12 is the α single phase. A holding temperature is preferably, for example, 700° C. or higher, and a supersaturated solid solution is preferably formed by rapid cooling from the holding temperature. However, a temperature at which the structure is transformed into the α single phase slightly varies depending on the components of the Fe—Cr—Co-based alloy. Therefore, it is preferable to set the holding temperature depending on the components based on a known phase diagram or the like.

It is considered that temperature holding time in the heat treatment (A) is preferably at least 30 minutes or more from a viewpoint of forming an α single phase structure. An upper limit of the temperature holding time is not particularly limited, but an excessively long holding time causes progress of uniformity and increases the manufacturing time and the manufacturing cost, and leads to possible oxidation of a powder surface and the like, which causes a bad influence on the magnetic characteristic.

In the heat treatment (A) and (B), (C), and (D), the spinodal decomposition of the α single phase structure occurs to form the two-phase separation structure. The longer the temperature holding time in a range of 500° C. to 620° C., the larger a Cr concentration difference between the first phase and the second phase. It is considered that the larger the Cr concentration difference, the better a high-frequency magnetic characteristic of an electromagnetic absorber.

The first phase may be elongated or flattened at any time before the electromagnetic absorber is manufactured. A specific method for elongating or flattening the first phase is not particularly limited, and examples thereof include the following.

As an example of a specific method for flattening the first phase, as shown in FIG. 14B, a two-phase separation structure is formed in a powder, and then the powder is flattened before being kneaded and shaped with a base material formed of a polymer. By the flattening, for example, an average aspect ratio of the powder may be set within a range of 3 to 50. By flattening the powder, the first phase contained in the powder is also flattened. FIG. 5 shows an example of the flattened powder 12. An upper part of FIG. 5 is a photograph of the flattened powder 12 in a plan view, and a lower part of FIG. 5 is a photograph of the flattened powder 12 in a cross-sectional view. As shown in FIG. 5, the flattened powder 12 becomes a flat plate shape. Since the Fe—Cr—Co-based alloy has high workability, the Fe—Cr—Co-based alloy is not pulverized even when subjected to such flattening, and can be formed into a shape having a high aspect ratio. In addition, the two-phase separation structure is maintained even after flattening.

On the other hand, it should be noted that when the spinodal decomposition is caused after the flattening, the flattening of the powder is achieved but the flattening of the first phase is not achieved. When the two-phase separation structure is formed in the powder, workability of the powder is slightly reduced, and it is difficult to perform the flattening. When a purpose of flattening is to flatten the powder, the flattening should be performed before formation of the two-phase separation structure. However, in the method for manufacturing the electromagnetic absorber 1 according to the present embodiment, the purpose of the flattening is to flatten the first phase. Therefore, the flattening of the powder is performed after the formation of the two-phase separation structure.

A flattening method is not particularly limited, and for example, a ball mill is preferably used. In the flattening using the ball mill, a rotation speed and milling time are important parameters. The higher the rotation speed, the higher a processing degree. In addition, the longer the milling time, the higher the processing degree. However, it should be noted that when the rotation speed and the milling time are set to excessive values, the powder is pulverized and the aspect ratio is decreased. According to the findings of the present inventors, low-load long-time ball milling with the rotation speed set to a lower value and the milling time set to a large value facilitates an increase in the aspect ratio. The rotation speed is preferably in a range of 50 rpm to 600 rpm, and the milling time is preferably within a range of more than 0 hour to 168 hours. It is preferable to search for a suitable combination of the rotation speed and the milling time within the range. A preferred combination found by the present inventors is shown in data of an example to be described later.

As shown in FIG. 14C, an example of a specific method for elongating the first phase is to cause the spinodal decomposition while applying the magnetic field to the powder. When the spinodal decomposition is caused while applying the magnetic field to the powder, the first phase formed in the powder has a shape in which grains are extended along one direction. Accordingly, the first phase can be elongated without flattening the powder.

As shown in FIG. 14E, the other example of the method for elongating the first phase is the elongation of the powder. For example, the powder can be elongated in one direction by filling the powder into the pipe-shaped container and processing the powder along one direction with respect to the container. However, as in the case of the flattening described above, the elongating should be performed before the spinodal decomposition occurs.

Both the flattening and the elongating may be applied to the powder 12. For example, as shown in FIG. 14D, elongating treatment of the first phase using the magnetic field and flattening treatment of the first phase by machining may be combined. As shown in FIG. 14E, elongating treatment of the first phase by the machining and the flattening treatment of the first phase by the machining may be combined. The first phase thus obtained has a flattened and elongated shape in one direction, such as an elliptical plate shape or a circular plate shape elongated in one direction.

The powder 12 after the elongating and/or the flattening is kneaded and shaped with the base material 11 formed of the polymer. Accordingly, the electromagnetic absorber 1 can be obtained. As described above, a specific material of the base material 11 is not particularly limited, and can be appropriately selected according to an application of the electromagnetic absorber 1. Therefore, kneading and shaping conditions may be appropriately selected from those suitable for the base material 11. A filling rate during the kneading is not particularly limited, and a mass of the powder 12 may be more than 0% and less than 100% with respect to a mass of the base material 11. As long as a small amount of the powder 12 is contained, a function of the electromagnetic absorber 1 can be exhibited, and as long as a small amount of the base material 11 is contained, a bulk body can be manufactured. On the other hand, from a viewpoint of ease of manufacturing, for example, the mass of the powder 12 is preferably in a range of about 30% to 70% with respect to a total mass of the base material 11 and the powder 12. The mass of the powder 12 may be in a range of 5% to 90% with respect to the mass of the base material 11. A shaping method is not particularly limited, and a known method such as compression molding, injection molding, extrusion molding, and rolling can be appropriately adopted.

In the above-described manufacturing method, a chemical component of the powder 12 before the spinodal decomposition may be within the above-described range as a chemical component of the powder 12 of the finally obtained electromagnetic absorber 1. An average equivalent circular diameter of the powder 12 before the spinodal decomposition may also be within the above-described range as the equivalent circular diameter of the powder 12 of the finally obtained electromagnetic absorber 1. However, although the workability of the powder 12 of the electromagnetic absorber 1 according to the present embodiment is high, the powder 12 may be slightly pulverized during the flattening. Therefore, an average equivalent circular diameter of the powder 12 before the flattening is usually slightly larger than that of the powder 12 of the finally obtained electromagnetic absorber 1. When the powder 12 is a spherical powder, it is presumed that the average equivalent circular diameter thereof is preferably several μm (for example, 2 μm) to 100 μm. The average equivalent circular diameter of the powder 12 may be 3 μm or more, or 5 μm or more. When the powder 12 is a flat powder, it is presumed that the average equivalent circular diameter thereof is preferably several hundred μm or less (for example, 500 μm or less). The average equivalent circular diameter of the powder 12 may be 400 μm or less, or 300 μm or less.

The embodiment using the Fe—Cr—Co-based alloy as the powder has been described above. On the other hand, a Cu—Ni—Co-based alloy and the Cu—Ni—Fe-based alloy may be used as materials of the powder 12. These alloys have relatively high workability, and form a two-phase separation modulated structure by the spinodal decomposition. Therefore, an electromagnetic absorber obtained by subjecting the Cu—Ni—Co-based alloy or the Cu—Ni—Fe-based alloy to the spinodal decomposition to form the two-phase separation modulated structure, and kneading and shaping the two-phase separation modulated structure with a base material also exhibits a good magnetic characteristic.

### EXAMPLES

An effect of one embodiment of the invention will be described more specifically with reference to examples. However, conditions in the examples are merely a condition example adopted to confirm feasibility and the effect of the invention. The invention is not limited to the condition example. The invention can adopt various conditions without departing from a gist of the invention as long as an object of the invention is achieved.

### Example 1: Evaluation of Magnetic Characteristic of Powder

An Fe-25Cr-12Co-1.5Ti atomized powder (average particle diameter: 45 μm or less) was subjected to various heat treatment. Heat treatment conditions were as follows.
(A) The temperature of the powder 12 was held at 655° C. for 80 minutes.
(B) The temperature of the powder 12 was lowered to 620° C. and held for 60 minutes.
(C) The temperature of the powder 12 was lowered to 600° C. and held for 120 minutes.
(D) The temperature of the powder 12 was lowered to 500° C. and held for 600 minutes.

A powder sample (a) was subjected to only the above heat treatment (A), a powder sample (b) was subjected to the above heat treatment (A) and (B), a powder sample (c) was subjected to the above heat treatment (A) to (C), and a powder sample (d) was subjected to the above heat treatment (A) to (D). Further, a powder not subjected to the heat treatment was used as a powder sample (As.) for comparison.

Further, the powder samples (a) to (d) and (As.) were subjected to powder compression molding to have a ring shape. The powder compression molding was performed under conditions of a pressure of 1 GPa and a pressure application time of 1 minute. The obtained ring shape had an outer diameter of 6.90 mm, an inner diameter of 3.07 mm, and a thickness of 0.9 mm to 1.3 mm. Further, the powder samples (a) to (d) and (As.) molded into the ring shape were heated to 200° C. at a temperature rising rate of 10° C./min, and then held at the temperature for 30 minutes. The heating temperature does not affect metal structures of the samples. High-frequency magnetic characteristics of the powder samples (a) to (d) and (As.) were evaluated by a vector network analyzer (VNA).

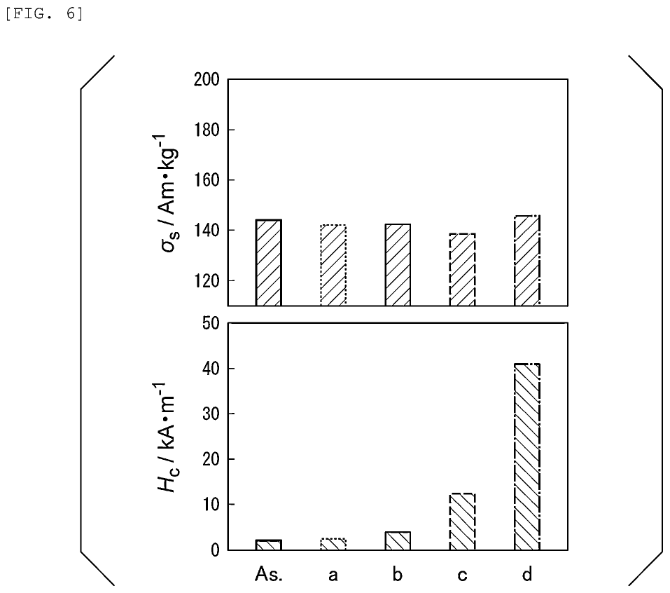

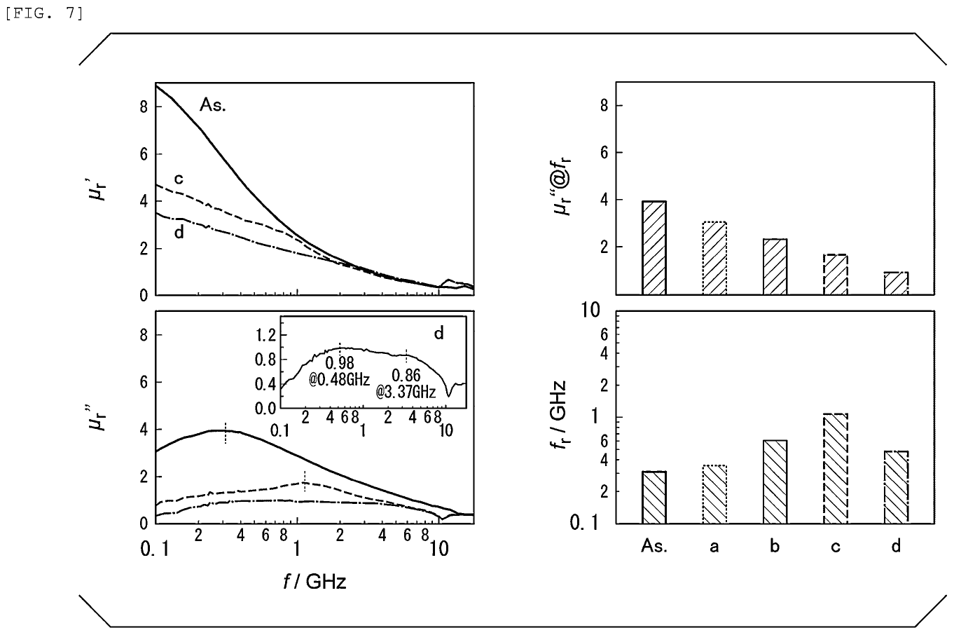

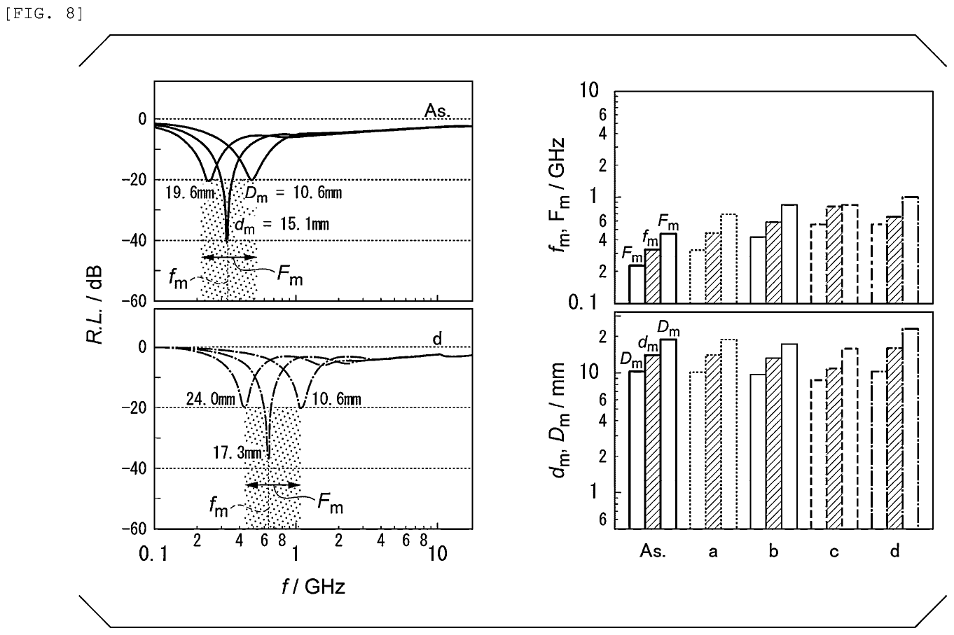

An evaluation result of the magnetic characteristics is shown in FIG. 6. An upper part of FIG. 6 shows saturation magnetization σₛ (unit: Am·kg⁻¹) of the powder samples (a) to (d) and (As.), and a lower part of FIG. 6 shows coercive force H_{c} (unit: kA·m⁻¹) of the powder samples (a) to (d) and (As.). It was confirmed that the coercive force He of the powder was dramatically enhanced through the heat treatment (B) to (D).

FIG. 2 shows a photograph of a structure of the powder sample (As.), and FIG. 3A shows a photograph of a structure of the powder sample (d). The photograph of the structure of the powder sample (As.) not subjected to the heat treatment exhibited a flat aspect, but in the powder sample (d) subjected to the heat treatment (A) to (D), a two-phase separation structure was clearly observed. FIG. 3B shows an elemental concentration mapping photograph of the powder sample (d). Four grayscale images included in FIG. 3B are all photographs at the same position, in which (a) is a COMPO image, (b) is an Fe concentration mapping image, (c) is a Cr concentration mapping image, and (d) is a Co concentration mapping image. In (b) to (d), image processing is performed so that the higher a concentration of an element to be mapped, the lighter the color. In the two-phase separation structure, it can be read from FIG. 3B that an Fe content and a Co content of a first phase are more than those of a second phase, and a Cr content of the second phase is more than that of the first phase.

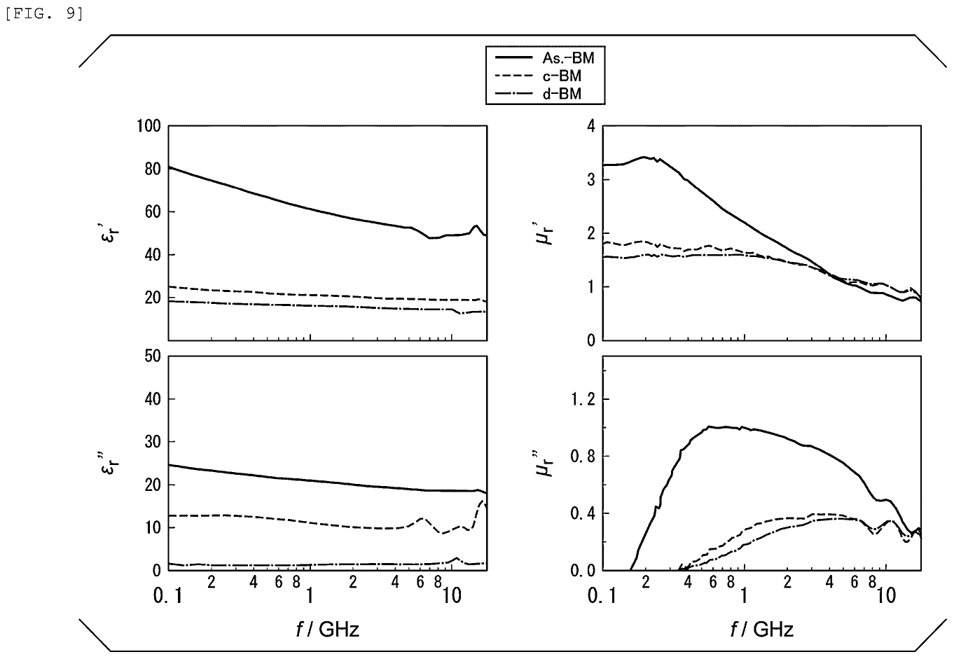

An evaluation result of the high-frequency magnetic characteristics is shown in FIG. 7. In FIG. 7, f is a frequency, and μᵣ is a complex relative permeability. μᵣ′ is a real part of the complex relative permeability, and μᵣ″ is an imaginary part of the complex relative permeability. μᵣ is a value that changes according to the frequency. A graph in an upper left part of FIG. 7 shows a relation between the frequency and the real part of the complex relative permeability, and a graph in a lower left part shows a relation between the frequency and the imaginary part of the complex relative permeability. A frequency at which the imaginary part of the complex relative permeability is maximized is a resonance frequency fᵣ. A lower right part of FIG. 7 shows a resonance frequency of each sample. An upper right part of FIG. 7 shows a value of the imaginary part of the complex relative permeability at the resonance frequency of each sample.

As shown in FIG. 7, the complex relative permeability μᵣ decreased as heat treatment time increased. In addition, it was clearly observed that the resonance frequency fᵣ tends to increase in the powder samples (b) to (d) in which the spinodal decomposition occurred.

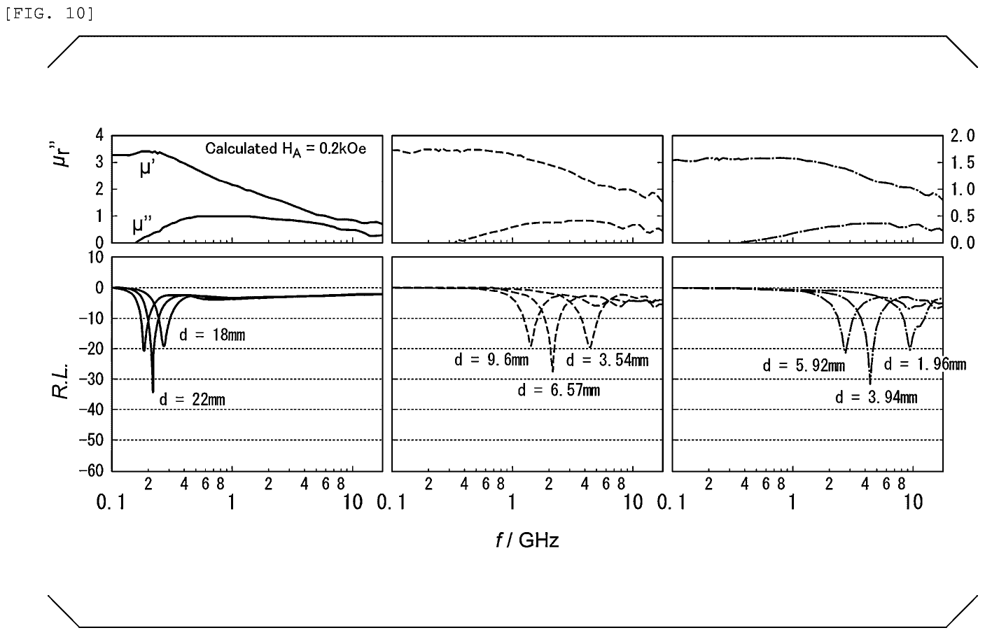

Further, an evaluation result of an electromagnetic wave absorption characteristic is shown in FIG. 8. In FIG. 8, R.L. is reflection loss. fₙ is a matching frequency, and Fₘ is a matching frequency domain. An upper left part of FIG. 8 shows an R.L. measurement result of the powder sample (As.), and a lower left part of FIG. 8 shows an R.L. measurement result of the powder sample (d). R.L. measurement results of the powder samples (a) to (c) are omitted. An upper right part of FIG. 8 shows Fₘ and fₘ of each sample, and a lower right part of FIG. 8 shows Dₘ and dₘ of each sample.

As shown in FIG. 8, it was clearly observed that both fₘ and Fₘ tend to increase in the powder samples (b) to (d) in which the spinodal decomposition occurred.

### Example 2: High-Frequency Magnetic Characteristic after Flattening

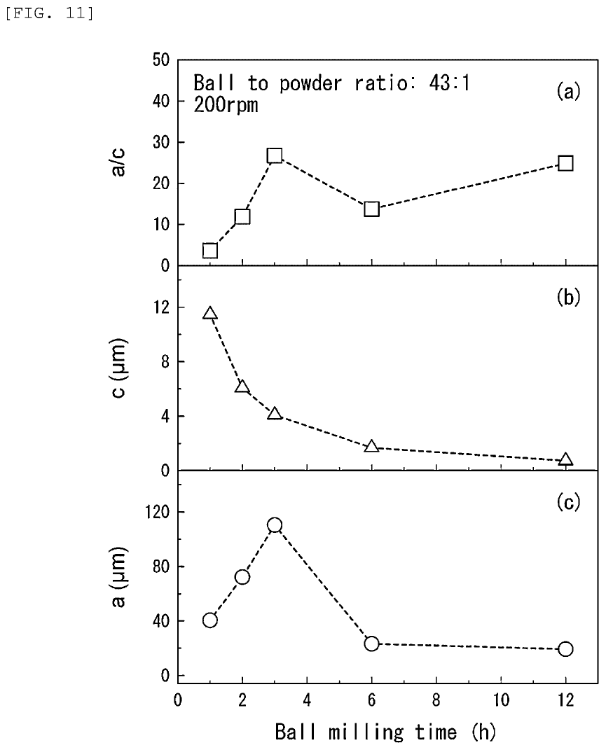

The above-described powder samples (As.), (c), and (d) were flattened using a ball mill. A rotation speed of the ball mill was 200 rpm, and milling time was 3 hours. Samples after flattening by the ball mill are hereinafter referred to as As.-BM, c-BM, and d-BM. Further, each of these samples As.-BM, c-BM, and d-BM was kneaded and shaped with a resin as a base material to prepare an electromagnetic absorber. A weight of a powder sample was 40% of a total weight of the powder sample and the resin. The obtained electromagnetic absorber was subjected to VNA measurement. A measurement result is shown in FIGS. 9 and 10.

FIG. 9 shows high-frequency magnetic characteristics of the samples As.-BM, c-BM, and d-BM. FIG. 10 shows electromagnetic wave absorption characteristics of the samples As.-BM, c-BM, and d-BM. As shown in FIGS. 9 and 10, it was confirmed that shift phenomenon of a resonance frequency to a high-frequency band by spinodal decomposition was maintained even after the flattening. Specifically, the μᵣ″ of the samples c-BM and d-BM in which the spinodal decomposition occurred was smaller than that of As.-BM (see an upper left part and a lower left part of FIG. 9). On the other hand, profiles of the samples c-BM and d-BM shifted to the higher frequency band than that of As.-BM (see an upper right part and a lower right part of FIG. 9). Further, R.L. profiles of the samples c-BM and d-BM also shifted to the higher frequency band than that of As.-BM (see FIG. 10).

### Example 3: Flattening Condition

A powder formed of an Fe—Cr—Co-based alloy was flattened using a ball mill. In a state where a rotation speed was constant at 200 rpm, a plurality of samples were prepared by appropriately changing milling time, and shapes and magnetic characteristics thereof were evaluated.

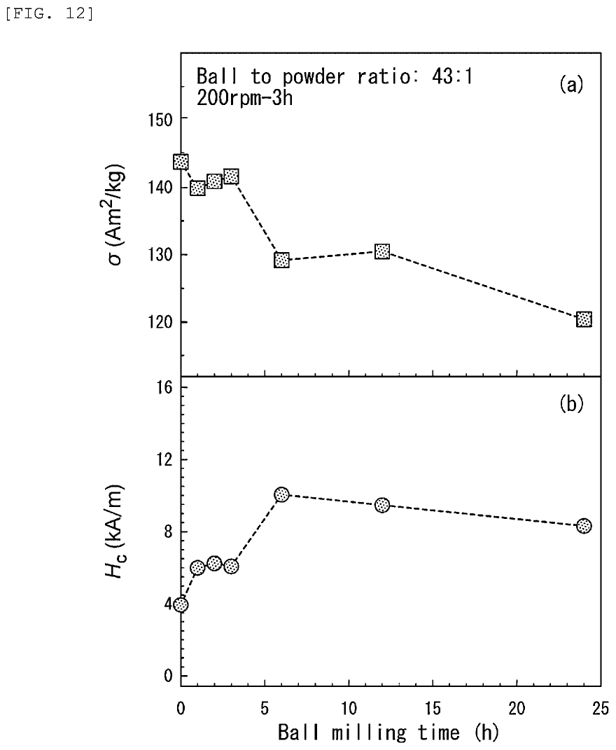

First, FIG. 11 shows an aspect ratio of the powder after the flattening. In FIG. 11, “a” is a major axis of the powder, and “c” is a minor axis of the powder. As shown in FIG. 11, an aspect ratio of the Fe—Cr—Co-based alloy could be increased to close to 30 by flattening the Fe—Cr—Co-based alloy. However, the milling time and the aspect ratio were not always proportional. A major axis of a sample having the milling time of 6 hours was much smaller than a major axis of a sample having the milling time of 3 hours, and thus the aspect ratio was decreased. This is considered to be because the powder was pulverized.

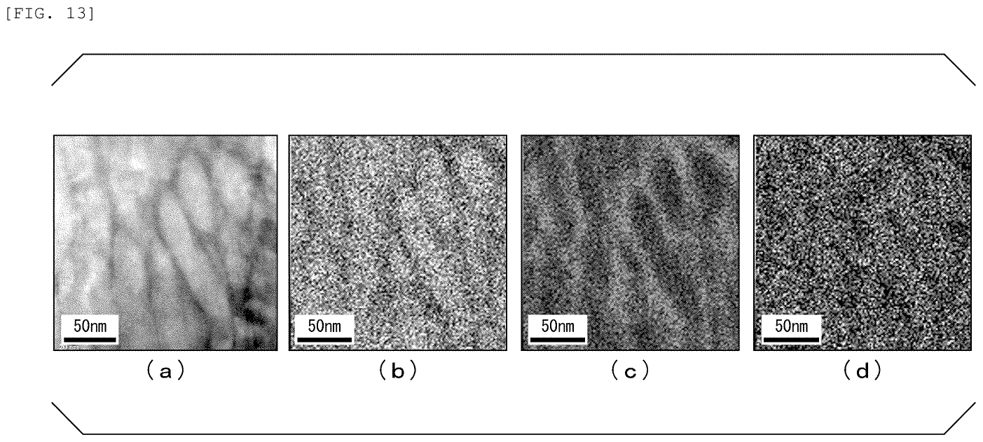

FIG. 12 shows a relation between the milling time and the magnetic characteristic of the powder. The coercive force H_{c} was maximized in the sample having the milling time of about 6 hours.

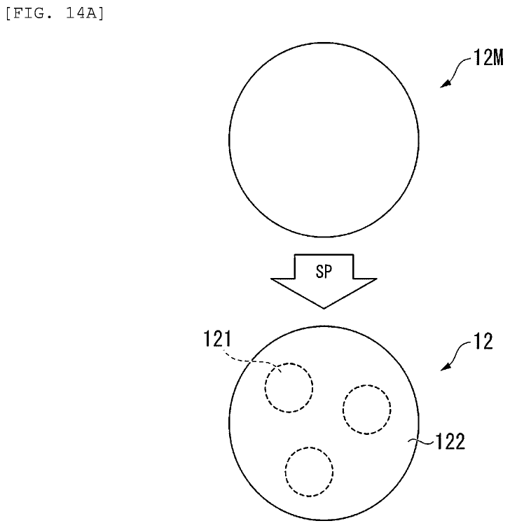

In addition, FIG. 13 shows an element mapping image of a powder c after ball milling treatment. Four grayscale images included in FIG. 13 are all photographs at the same position, in which (a) is a COMPO image, (b) is an Fe concentration mapping image, (c) is a Cr concentration mapping image, and (d) is a Co concentration mapping image. In (b) to (d), image processing is performed so that the higher a concentration of an element to be mapped, the lighter the color. It can be seen from FIG. 13 that a two-phase separation structure is maintained even after the ball milling treatment.

### Example 4: Observation of Flattened First Phase

A powder formed of an Fe—Cr—Co-based alloy was subjected to
heat treatment A of holding at 655° C. for 80 minutes,
heat treatment B of holding at 620° C. for 60 minutes,
heat treatment C of holding at 600° C. for 120 minutes, and
heat treatment D of holding at 500° C. for 10 hours.

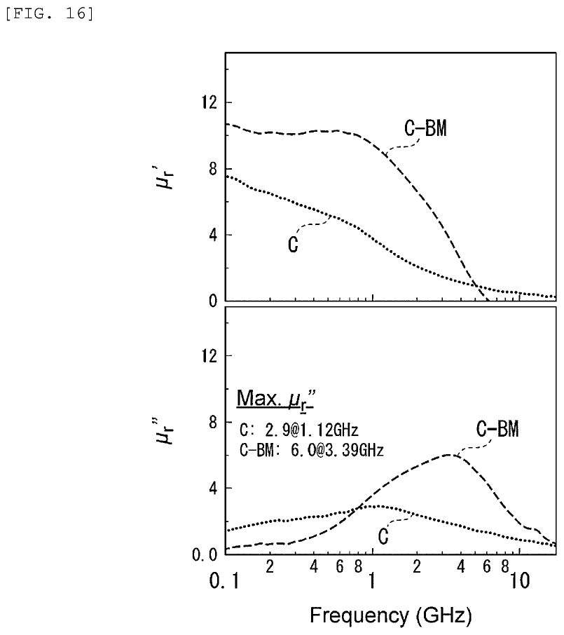

In a period from completion of the heat treatment C to start of the heat treatment D, a temperature of the powder was slowly lowered at a temperature decrease rate of 5° C./hour. The powder thus obtained was subjected to ball milling treatment for 3 hours to prepare a flat powder. A rotation speed during the ball milling treatment was set to 200 rpm. Then, a cross-sectional shape and an element distribution state of the flat powder were captured. A result is shown in FIG. 15.

As shown in FIG. 15, in the powder obtained under the above-described conditions, concentration distribution of Fe, Cr, and Co were layered. That is, a first phase contained in the powder obtained under the above-described conditions was significantly flattened.

### Example 5: Complex Relative Permeability Characteristic after Flattening

A powder formed of an Fe—Cr—Co-based alloy was subjected to
heat treatment A of holding at 655° C. for 80 minutes,
heat treatment B of holding at 620° C. for 60 minutes, and
heat treatment C of holding at 600° C. for 120 minutes.

A part of the powder thus obtained was subjected to ball milling treatment for 3 hours to prepare a flat powder. A rotation speed during the ball milling treatment was set to 200 rpm. A powder that had not been subjected to the ball milling treatment and a powder that had been subjected to the ball milling treatment were each kneaded and shaped with a resin as a base material to prepare an electromagnetic absorber. An amount of a powder sample was 56% by volume of a total amount of the powder sample and the resin.

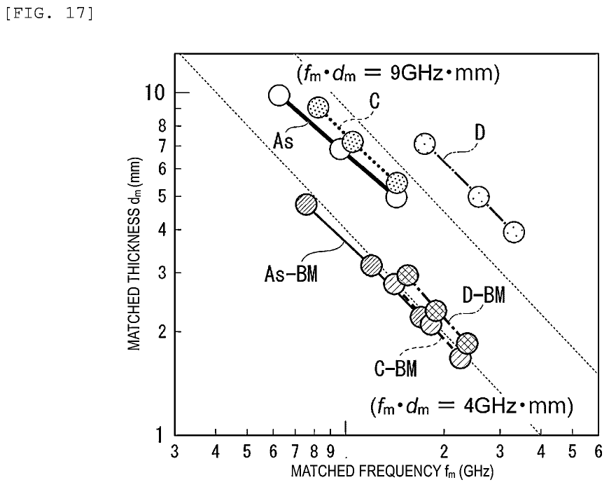

A complex relative permeability of the obtained electromagnetic absorber was evaluated. A measurement result is shown in FIG. 16. An upper graph of FIG. 16 is a graph showing a relation between a frequency and μᵣ′, and a lower graph is a graph showing a relation between the frequency and μᵣ″. As described above, μᵣ′ is a real part of the complex relative permeability, and μᵣ″ is an imaginary part of the complex relative permeability.

A complex relative permeability of an electromagnetic absorber manufactured from a flattened powder (“C-BM” in FIG. 16) was significantly superior to that of an electromagnetic absorber manufactured from an unflattened powder (“C” in FIG. 16). A peak of μᵣ″ of the powder C-BM was significantly shifted to the higher frequency side than a peak of μᵣ″ of the powder C.

### Example 6: Effect of Flattening Treatment on fₘ×dₘ in Reflection Loss R.L.

A powder formed of an Fe—Cr—Co-based alloy was subjected to
heat treatment A of holding at 655° C. for 80 minutes,
heat treatment B of holding at 620° C. for 60 minutes,
heat treatment C of holding at 600° C. for 120 minutes, and
heat treatment D of holding at 500° C. for 10 hours.

In a period from completion of the heat treatment A to start of the heat treatment B, a temperature of the powder was lowered from 655° C. to 620° C. over 7 minutes. In a period from the completion of the heat treatment B to the start of the heat treatment C, the temperature of the powder was lowered from 620° C. to 600° C. over 4 minutes. In a period from completion of the heat treatment C to start of the heat treatment D, a temperature of the powder was lowered from 600° C. to 500° C. over 20 hours. However, only heat treatment A, B, and C were performed on a part of the powder. After completion of the heat treatment, the powder was taken out of a furnace and left to stand until a temperature thereof reached a room temperature. In addition, the heat treatment was not performed on a part of the powder.

Then, a part of various powder thus obtained was subjected to ball milling treatment for 3 hours to prepare a flat powder. A rotation speed during the ball milling treatment was set to 200 rpm.

Hereinafter, an experimental result will be described using the following reference signs.
As: a powder not subjected to either the heat treatment or the ball milling treatment
C: a powder subjected to the heat treatment A, B, and C but not subjected to the ball milling treatment
D: a powder subjected to the heat treatment A, B, C, and D but not subjected to the ball milling treatment
As-BM: a powder not subjected to the heat treatment but subjected to the ball milling treatment
C-BM: a powder subjected to the heat treatment A, B, and C, and the ball milling treatment
D-BM: a powder subjected to the heat treatment A, B, C, and D, and the ball milling treatment

Each of these powder was kneaded and shaped with a resin as a base material to prepare an electromagnetic absorber. Then, a matched frequency fₘ and a matched thickness dₘ of the electromagnetic absorber a: reflection loss R.L were evaluated. R.L is a value defined by the following equation.

$$\begin{matrix}R . L . = 20 log \vert \frac{( {Z}_{i n} - {Z}_{0} )}{( {Z}_{i n} + {Z}_{0} )} \vert \\ {Z}_{i n} = {Z}_{0} \sqrt{\frac{{μ}_{r}}{{ε}_{r}}} tanh ( j \frac{2 π fd}{c} \sqrt{{ε}_{r} {μ}_{r}} )\end{matrix} \qquad [ Equation 1 ]$$

Definitions of reference numerals included in the above-described equations are as follows.
Z₀: characteristic impedance
Zᵢₙ: input impedance
μᵣ: complex relative permeability
εᵣ: complex relative permittivity
j: imaginary unit
f: frequency
d: thickness of electromagnetic absorber
c: speed of light

A matched frequency fₘ is a frequency at which R.L is minimized in a predetermined matched thickness dₘ. In general, since the frequency and the thickness of the electromagnetic absorber are in an anti-proportional relation, the smaller a value of fₘ×dₘ, the thinner the thickness of the electromagnetic absorber when compared at the same frequency.

FIG. 17 shows an evaluation result of the matched frequency fₘ and the matched thickness dₘ of the electromagnetic absorber. FIG. 17 is a scatter diagram in which fₘ and dₘ of the electromagnetic absorber obtained from various powder are plotted using fₘ as a horizontal axis and dₘ as a vertical axis. FIG. 17 shows that the matched frequency fₘ is shifted to a high-frequency side by the heat treatment. FIG. 17 also shows that fₘ×dₘ is improved by flattening treatment.

### REFERENCE SIGNS LIST

1: electromagnetic absorber
11: base material
12: powder
121: first phase
122: second phase
12M: material powder
SP: heat treatment for causing spinodal decomposition
SP+MF: heat treatment for causing spinodal decomposition while applying magnetic field
BM: flattening of powder
EX: elongation of powder

1. An electromagnetic absorber comprising:
a base material formed of a polymer; and
a powder dispersed in the base material, wherein
the powder is formed of an Fe—Cr—Co-based alloy having a two-phase separation structure including a first phase and a second phase,
an Fe content and a Co content of the first phase are more than those of the second phase,
a Cr content of the second phase is more than that of the first phase, and
the two-phase separation structure is a modulated structure.

2. The electromagnetic absorber according to claim 1, wherein the first phase is elongated or flattened.

3. The electromagnetic absorber according to claim 1, wherein the first phase has an elliptical plate shape or a circular plate shape elongated in one direction.

4. The electromagnetic absorber according to claim 2, wherein an average aspect ratio of the powder is within a range of 3 to 50, and the first phase is flattened accordingly.

5. The electromagnetic absorber according to claim 1, wherein components of the powder contain;
Cr: 10 to 50 mass %,
Co: 0 to 30 mass %, and
one or more selected from the group consisting of Ti, Zr, Hf, Al, V, Nb, and Si: 0 to 5 mass % in total,
with the balance being Fe and impurities.

6. A method for manufacturing an electromagnetic absorber, comprising:
a step of forming a two-phase separation structure including a first phase and a second phase by causing spinodal decomposition in a metal structure of a powder formed of an Fe—Cr—Co-based alloy, wherein an Fe content and a Co content of the first phase are more than those of the second phase, and a Cr content of the second phase is more than that of the first phase; and
a step of obtaining an electromagnetic absorber by kneading and shaping the powder with a base material formed of a polymer.

7. The method for manufacturing an electromagnetic absorber according to claim 6, further comprising:
a step of elongating or flattening the first phase.

8. The method for manufacturing an electromagnetic absorber according to claim 7, wherein the step of elongating or flattening the first phase is a step of elongating and/or flattening the powder having the two-phase separation structure between the step of forming the two-phase separation structure and the step of obtaining the electromagnetic absorber, so that the powder has an average aspect ratio within a range of 3 to 50.

9. The method for manufacturing an electromagnetic absorber according to claim 6, wherein the spinodal decomposition is caused by holding the powder at a temperature equal to or lower than that of a two-phase separation surface.

10. The method for manufacturing an electromagnetic absorber according to claim 6, wherein components of the powder contain;
Cr: 10 to 50 mass %,
Co: 0 to 30 mass %, and
one or more selected from the group consisting of Ti, Zr, Hf, Al, V, Nb, and Si: 0 to 5 mass % in total,
with the balance being Fe and impurities.
